(19) United States
(12) Patent Application Publication
(10) Pub. No.: US 2024/0170478 A1
(43) Pub. Date: May 23, 2024

(54) ELECTROSTATIC DISCHARGE PROTECTION DEVICE INCLUDING PARASITIC MOSFET FORMED USING TRENCH

(71) Applicant: Allegro MicroSystems, LLC, Manchester, NH (US)

(72) Inventors: Chung C. Kuo, Manchester, NH (US); Maxim Klebanov, Palm Coast, FL (US); James McClay, Dudley, MA (US); Sagar Saxena, Manchester, NH (US)

(73) Assignee: Allegro MicroSystems, LLC, Manchester, NH (US)

(21) Appl. No.: 18/058,318

(22) Filed: Nov. 23, 2022

(51) Int. Cl. H01L 27/02

(52) U.S. Cl. CPC H01L 27/0274

(57) ABSTRACT

In one aspect, a semiconductor device includes a first region, a second region and a trench separating the first and the second regions. The trench includes a trench liner that includes a dielectric, and a semiconductor material surrounded by the trench liner. The first region includes a first buried layer implanted in a substrate, a first stack of layers that includes a first middle layer located above the first buried layer, a first well located on and in contact with the first middle layer and a second well in contact with the first well. The second region includes a second stack of layers. In response to a voltage difference between the first and the second regions exceeding a threshold voltage, a conduction current is formed. A distance of the first stack of layers to the trench controls the conduction current to activate a transistor to function as a voltage clamp.

### BACKGROUND

Bipolar-CMOS-DMOS (BCD) technology integrates bipolar transistors with complementary metal oxide semiconductor (CMOS) logic and double diffused metal-oxide-semiconductor (DMOS) transistors. High Voltage BCD technologies (e.g., with operating voltages in excess of 80V), are prone to a circuit failure due to turn-on of a parasitic transistor between wells during an electrostatic discharge event (ESD) event.

Power clamps are circuits that can be used to protect other circuitry from damage due to overvoltage conditions caused by, for example, ESD and other noise events. ESD induced failure is a major concern for integrated circuits in advanced and main-stream technologies. This reliability issue is further worsened in high-voltage technologies because of the latch-up hazard.

### SUMMARY

In one aspect, a semiconductor device includes a first region, a second region and a trench separating the first region from the second region. The trench includes a trench liner that includes a dielectric, and a semiconductor material surrounded by the trench liner. The first region includes a first buried layer implanted in a substrate, a first stack of layers that includes a first middle layer located above the first buried layer, a first well located on and in contact with the first middle layer and a second well in contact with the first well. The second region includes a second stack of layers. The trench is in contact with the second well and extends into the substrate below the first buried layer. In response to a voltage difference between the first region and the second region exceeding a threshold voltage, a conduction current is formed. A distance of the first stack of layers to the trench controls the conduction current to activate a transistor to function as a voltage clamp. A source of the transistor is formed by the first stack of layers, a gate of the transistor is formed by the second stack of layers, and a drain of the transistor is formed in the substrate. The gate of the transistor and the drain of the transistor are electrically tied to each other. A gate dielectric of the transistor is formed by the trench liner.

### DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1A is a cross-sectional view of an example of a portion of a semiconductor device that includes an example of an electrostatic discharge (ESD) clamp;

FIG. 1B is a cross-sectional view of the ESD clamp depicted in FIG. 1A with a parasitic metal-oxide-semiconductor field-effect transistor (MOSFET) overlaid;

FIG. 1C is a cross-sectional view of the ESD clamp depicted in FIG. 1A with a connector used to bias a trench;

FIG. 2 is a cross-sectional view of another example of the portion of the semiconductor device that includes another example of the ESD clamp;

FIG. 3 is a graph of an example of a trigger voltage of the ESD clamp of FIG. 1A being reached when the distance between a stack of layers and a trench is about 8 microns; and

FIG. 4 is a graph of an example of trigger voltage of the ESD clamp of FIG. 1A not being reached when the distance between the stack of layers and the trench is about 14 microns.

### DETAIL DESCRIPTION

Described herein are techniques to fabricate a semiconductor device that includes an electrostatic discharge (ESD) clamp. The ESD clamp includes a parasitic metal-oxide-semiconductor field-effect transistor (MOSFET) formed using a trench (sometimes called “an isolation trench”). In one example, the ESD clamp is a voltage clamp.

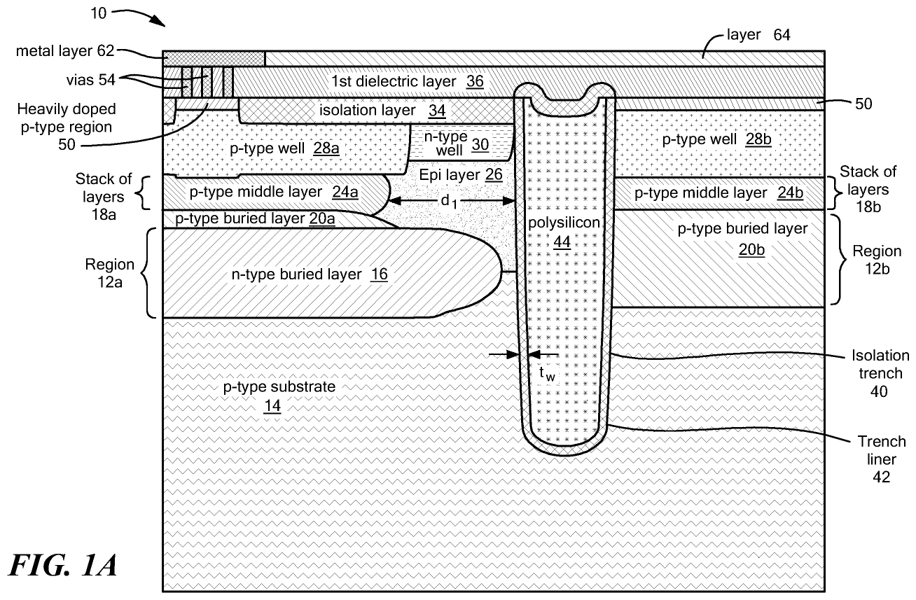

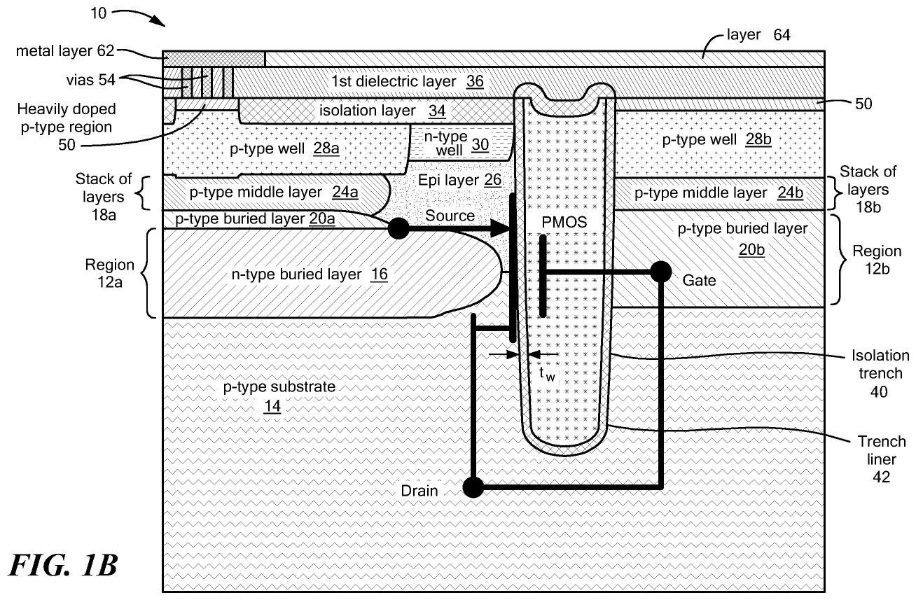

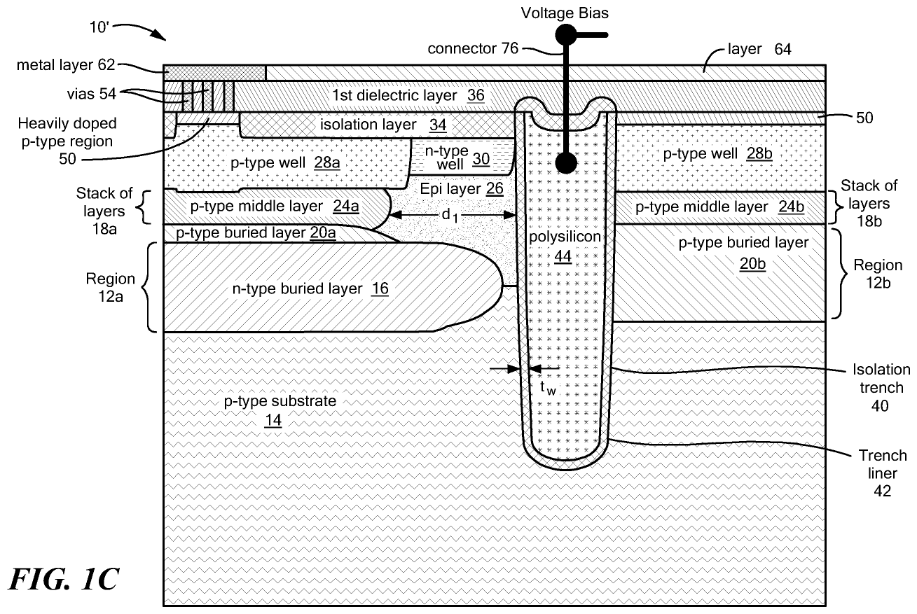

Referring to FIGS. 1A and 1B, an example of a semiconductor device is a semiconductor device 10. In one example, the semiconductor device is a reduced injection diode (RID). In one example, when the RID is operated in forward-bias mode, it reduces injection of minority carriers into the substrate.

The semiconductor device 10 includes a p-type substrate 14, a first region 12a and a second region 12b. The first region 12a includes a n-type buried layer 16 implanted into the p-type substrate 14, and a stack of layers 18. The stack of layers 18 includes a p-type buried layer 20a on the n-type buried layer 16, a p-type buried middle layer 24a on the p-type buried layer 20a, and a p-type well 28a on the p-type middle layer 24a.

The first region 12a also includes a n-type epitaxial layer 26 on the n-type buried layer 16 and in contact with the stack of layers 18. The first region 12a further includes a n-type well 30 at a certain distance from or in contact with the p-type well 28a.

The second region 12b includes a p-type buried layer 20b implanted in the p-type substrate 14, a p-type middle layer 24b on the p-type buried layer 20b, and a p-type well 28b on the p-type middle layer 24b.

A trench 40 separates the first region 12a from the second region 12b. The trench 40 includes a trench liner 42 that forms a trench wall around the trench 40 and has a thickness t_{W}. In one example, the thickness t_{w} is about 0.3 microns to 1.0 microns±0.1 microns. The trench liner 42 is a dielectric (e.g., an oxide). The trench 40 is filled with a polycrystalline silicon 44.

The trench 40 is in contact with the n-type well 30, the n-type epitaxial layer 26, the p-type substrate 14, the p-type buried layer 20b, p-type middle layer 24b and the p-type well 28a. As will be further explained herein, the trench 40 is used to form a parasitic p-type MOSFET that functions as an ESD (e.g., voltage) clamp.

The semiconductor device 10 also includes an isolation layer 36 on the p-type well 28a and the n-type well 30; a first dielectric layer 36 on the isolation layer 34, the trench 40 and the layer 32; a metal layer 62, and a dielectric (e.g., an oxide) layer 64 on the first dielectric layer 36. The semiconductor device 10 further includes a heavily doped p-type region 50 on the p-type well 28a, and contacts 54 extending through the dielectric layer 36 connecting the heavily doped p-type region 50 with the metal layer 62.

The distance d₁ between the stack of layers 18a and the trench 40 determines whether a conduction current (sometimes called a “leakage current”) is formed. Traditionally engineers design devices that avoid formation of the conduction current. However, the device 10 is constructed to form a conduction current in order to form a parasitic p-type MOSFET that functions as an ESD clamp to protect portions (e.g., the n-type epitaxial layer 26, the n-type well 30 and the n-type buried layer 16) of the semiconductor device 10 from overvoltage.

In one example, if the distance d₁ is less than 8 microns (e.g., 4 microns) a conduction current could be formed if the voltage difference between the first region 12a and the second region 12b is greater than a critical voltage (e.g., 100 volts±10 volts). The critical voltage activates a p-type MOSFET 100, where a source of the p-type MOSFET 100 is formed by the stack of layers 18a, a gate dielectric of the p-type MOSFET 100 is formed by the trench liner 42, a gate of the p-type MOSFET 100 is formed by a stack of layers 18b and a drain of the p-type MOSFET 100 is formed in the p-type substrate 14. The stack of layers 18b includes the p-type buried layer 20b, the p-type middle layer 24b and the p-type well 28b. The gate of the p-type MOSFET 100 and the drain of the p-type MOSFET 100 are electrically tied to each other. Referring to FIG. 1C, an example of the semiconductor device 10 (FIG. 1A) is a semiconductor device 10′. The semiconductor device 10′ includes a connector 76. One end of the connector is in the polysilicon 44 and the other end is biased by a voltage. Biasing the isolation trench 40 provides another dynamic control factor over the gate threshold voltage. In one example, in terms of control effectiveness, semiconductor device 10′ may provide about 50% reduction in comparison with that with the semiconductor device 10 that has the polysilicon 44 floating.

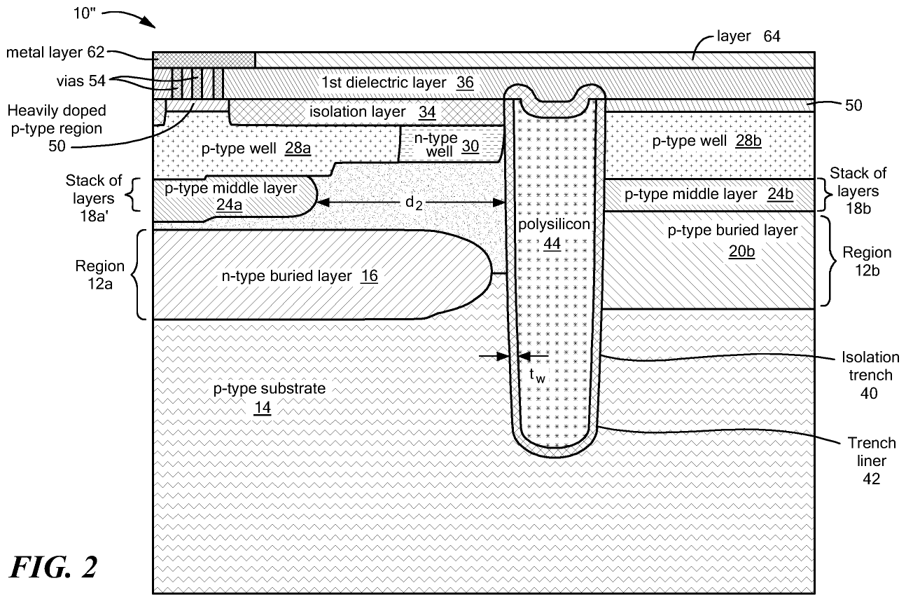

Referring to FIG. 2, an example of the semiconductor device 10 (FIG. 1A) is a semiconductor device 10″. The semiconductor device 10′ is the same as the semiconductor device 10 (FIG. 1A) except a stack of layers 18a′ does not include the p-type buried layer 20a (FIG. 1A). With the p-type buried layer 20a (FIG. 1A) removed a distance d₂ between the stack of layers 18′ and the trench 40 is longer than d₁. With a d₂ being longer than d₁, the trigger voltage of the p-type MOSFET 100 is higher for the semiconductor device 10″ than the trigger voltage of the p-type MOSFET 100 for the semiconductor device 10 (FIG. 1A).

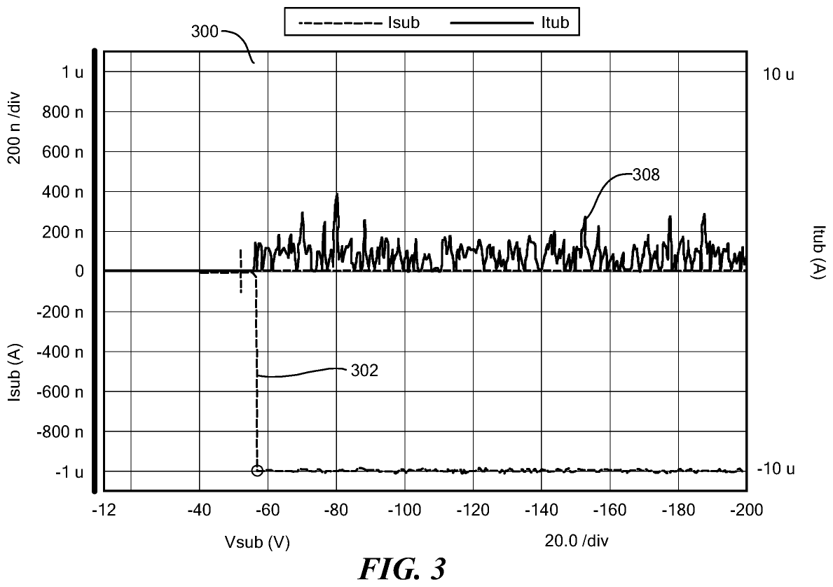

Referring to FIG. 3, a graph 300 depicts an example indicating that a trigger voltage of the semiconductor device 10 (FIG. 1A) is reached when d₁ is 8 microns. For example, a drain current Isub is depicted by a plot 302, which indicates that the trigger voltage occurs at 55 volts because the expected threshold voltage of the p-type MOSFET is 55V. Isub is the substrate current and also a drain current of the p-type MOSFET. A current Itub is depicted by a plot 306. Itub is the tub current, which is the total of current flow within the n-epi layer, n-type well and n-type buried layer.

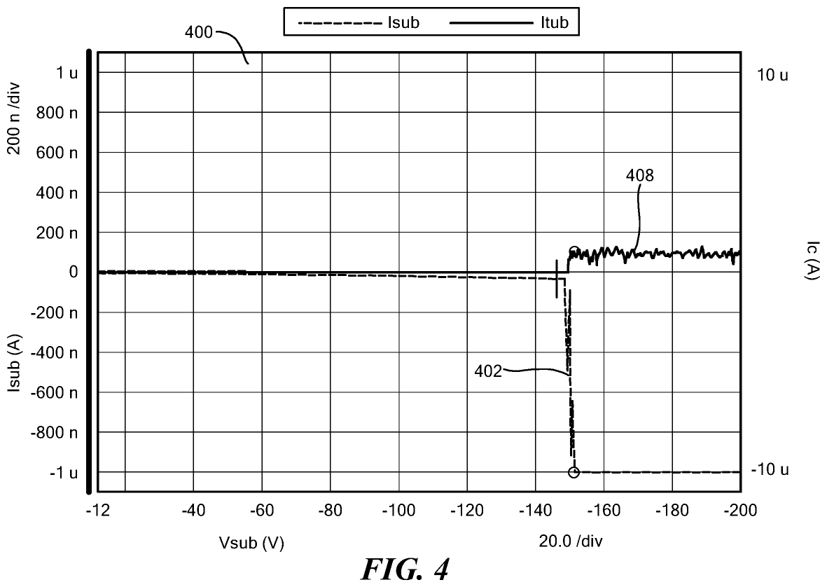

Referring to FIG. 4, a graph 400 depicts an example indicating that the trigger voltage of the semiconductor device 10 (FIG. 1A) is not reached when d₁ is 14 microns. For example, current Isub is depicted by a plot 402, which indicates that the trigger voltage is not reached; but rather, the expected breakdown voltage of 150V of the trench isolation (or the actual p-n junction breakdown voltage between the n-type buried layer 16 (FIG. 1A) and the p-type substrate 14 (FIG. 1A)).

The semiconductor devices (e.g., the semiconductor device 10, the semiconductor device 10′) described herein are not limited to the specific examples described. For example, the doping may be opposite than what is described (e.g., n-type doping may be replaced by p-type doping and p-type doping may be replaced by n-type doping) so that a parasitic n-type MOSFET is formed using the trench.

Having described preferred embodiments, which serve to illustrate various concepts, structures, and techniques, which are the subject of this patent, it will now become apparent to those of ordinary skill in the art that other embodiments incorporating these concepts, structures and techniques may be used.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A semiconductor device comprising:
a first region;
a second region; and
a trench separating the first region from the second region, the trench comprising a trench liner comprising a dielectric, and a semiconductor material surrounded by the trench liner;
wherein the first region comprises:
a first buried layer implanted in a substrate;
a first stack of layers comprising:
a first middle layer located above the first buried layer;
a first well located on and in contact with the first middle layer; and
a second well in contact with the first well,
wherein the second region comprises a second stack of layers,
wherein the trench is in contact with the second well and extends into the substrate below the first buried layer,
wherein in response to a voltage difference between the first region and the second region exceeding a threshold voltage, a conduction current is formed,
wherein a distance of the first stack of layers to the trench controls the conduction current to activate a transistor to function as a voltage clamp,
wherein a source of the transistor is formed by the first stack of layers, a gate of the transistor is formed by the second stack of layers and a drain of the transistor is formed in the substrate,
wherein the gate of the transistor and the drain of the transistor are electrically tied to each other, and
wherein a gate dielectric of the transistor is formed by the trench liner.

2. The semiconductor device of claim 1, further comprising an epitaxial layer in contact with the first buried layer, the first middle layer, the first well, the second well, and the trench.

3. The semiconductor device of claim 2, wherein the first stack of layers further comprises a second buried layer in contact with the first buried layer, the first middle layer and the epitaxial layer.

4. The semiconductor device of claim 3, wherein the first buried layer and the second well have a first-type dopant, and
wherein the substrate, the first middle layer, the first well, and the second buried layer have a second-type dopant,
wherein the first-type dopant is one of a n-type dopant or a p-type dopant, and
wherein the second-type dopant is the other one of the n-type dopant or the p-type dopant.

5. The semiconductor device of claim 4, wherein the first buried layer and the second well have a first-type dopant, and
wherein the substrate, the first middle layer, and the first well,
wherein the first-type dopant is one of a n-type dopant or a p-type dopant, and
wherein the second-type dopant is the other one of the n-type dopant or the p-type dopant.

6. The semiconductor device of claim 1, wherein the first stack of layers is separated from the trench by less than 8 microns.

7. The semiconductor device of claim 1, wherein the first stack of layers is separated from the trench by about 4 microns.

8. The semiconductor device of claim 1, wherein the threshold voltage is greater than 90 volts.

9. The semiconductor device of claim 1, wherein the threshold voltage is greater than 100 volts.

10. The semiconductor device of claim 1, wherein the semiconductor material is silicon.

11. The semiconductor device of claim 10, wherein the silicon is polycrystalline silicon.

12. The semiconductor device of claim 1, wherein the second stack of layers comprises:
a third buried layer implanted in the substrate;
a second middle layer directly on and in contact with the third buried layer; and
a third well directly on and in contact with the second middle layer.

13. The semiconductor device of claim 12, wherein the third buried layer, the second middle layer and the third well are in direct contact with the trench.

14. The semiconductor device of claim 1, wherein the transistor is a p-type metal-oxide-semiconductor field-effect transistor (MOSFET).

15. The semiconductor device of claim 1, wherein the transistor is a n-type metal-oxide-semiconductor field-effect transistor (MOSFET).
